(19) United States
(12) Patent Application Publication
(10) Pub. No.: US 2026/0011384 A1
(43) Pub. Date: Jan. 8, 2026

(54) MEMORY DEVICE INCLUDING OTP (ONE TIME PROGRAMMABLE) CELLS AND METHOD OF OPERATING THE SAME

(71) Applicant: Samsung Electronics Co., Ltd., Suwon-si (KR)

(72) Inventor: DAESHIK KIM, Suwon-si (KR)

(21) Appl. No.: 19/218,628

(22) Filed: May 27, 2025

(30) Foreign Application Priority Data
Jul. 4, 2024 (KR) 10-2024-0088345

(51) Int. Cl. G11C 17/18; G11C 5/14; G11C 16/26; G11C 16/34; G11C 17/02

(52) U.S. Cl. CPC G11C 17/18; G11C 5/145; G11C 16/26; G11C 16/3459; G11C 17/02

(57) ABSTRACT

A memory device may include a memory cell array, a write driver, and a sensing circuit. The memory cell array may include a normal cell connected to a bit line and a one time programmable (OTP) cell connected to the bit line. A program state of the normal cell may be determined by a first reference resistance and a program state of the OTP cell may be determined by a second reference resistance smaller than the first reference resistance. The write driver may perform a first OTP write operation on the OTP cell, and a sensing circuit may determine whether the first OTP write operation on the OTP cell is passed. The write driver may perform a second OTP write operation on the OTP cell experiencing a failure of the first OTP write operation.

### CROSS-REFERENCE TO RELATED APPLICATION(S)

This application claims priority under 35 U.S.C. § 119 to Korean Patent Application No. 10-2024-0088345 filed on Jul. 4, 2024, in the Korean Intellectual Property Office, the disclosure of which is incorporated by reference herein in its entirety.

### BACKGROUND

Embodiments of the present disclosure described herein relate to a semiconductor device, and more particularly, relate to a memory device including a magnetic tunnel junction element and an operating method thereof.

Nowadays, various types of electronic devices are being used. As a high-speed and low-power electronic device is required, the electronic device may require a memory device satisfying high-reliability, high-speed, and low-power consumption characteristics. To satisfy the required characteristics, a magnetic memory element has been suggested as a memory element of the memory device. Because the magnetic memory element operates at a high speed and provides a nonvolatile characteristic, the magnetic memory element may be on the spotlight as a next-generation semiconductor memory element.

In general, the magnetic memory element may include a magnetic tunnel junction (MTJ) element. The MTJ element may include two magnetic materials and an insulating layer interposed therebetween. A resistance value of the MTJ element may vary depending on magnetization directions of two magnetic materials. For example, the MTJ element may have a great resistance value when the magnetization directions of two magnetic materials are anti-parallel to each other and may have a small resistance value when the magnetization directions of two magnetic materials are parallel to each other. Data may be written or read by using a difference of the resistance values.

Data necessary to manage the magnetic memory device may be stored and managed in one time programmable (OTP) cells. The OTP cells may be implemented by applying a high voltage to a conventional MTJ element such that the breakdown is caused; in this case, there are needs to prevent the high voltage from affecting any other MTJ elements and to improve a resistance distribution of MTJ elements. Accordingly, in general, normal cells where user data are stored and the OTP cells are disposed in independent memory cell arrays. However, the above configuration causes the increase in the area of the memory cell array, the increase in the area of a write driver, and the increase in manufacturing costs.

### SUMMARY

Embodiments of the present disclosure provide a memory device reducing the area and manufacturing costs by disposing normal cells of a magnetic memory device and OTP cells in one memory cell array.

Embodiments of the present disclosure provide a memory device having improved durability by minimizing an influence of OTP cells on normal cells adjacent thereto during an OTP write operation.

According to an embodiment, a memory device may include a memory cell array that includes a normal cell connected to a bit line and a one time program (OTP) cell connected to the bit line, a program state of the normal cell being determined by a first reference resistance and a program state of the OTP cell being determined by a second reference resistance smaller than the first reference resistance, a write driver that performs a first OTP write operation on the OTP cell, and a sensing circuit that determines whether the first OTP write operation on the OTP cell is passed. The write driver may perform a second OTP write operation on the OTP cell when the first OTP write operation on the OTP cell is failed.

According to an embodiment, a memory device may include a memory cell array that includes normal cells whose program states are determined using a first reference resistance and one time programmable (OTP) cells whose program states are determined using a second reference resistance less than the first reference resistance, a write driver that performs a plurality of OTP write operations on the OTP cells, and a sensing circuit that determines whether the plurality of OTP write operations are passed, by using a third reference resistance. Each of the normal cells and each of the OTP cells may include a magnetic tunnel junction element.

According to an embodiment, a method of operating a memory device in which a normal cell whose program state is determined using a first reference resistance and a one time programmable (OTP) cell whose program state is determined using a second reference resistance are connected to the same bit line may include performing a first OTP write operation on the OTP cell, determining whether the first OTP write operation on the OTP cell is passed, and performing a second OTP write operation on the OTP cell when the first OTP write operation on the OTP cell is failed. A value of the second reference resistance may be smaller than a value of the first reference resistance.

### BRIEF DESCRIPTION OF THE FIGURES

The above and other objects and features of the present disclosure will become apparent by describing in detail embodiments thereof with reference to the accompanying drawings.

FIG. 1 is a diagram illustrating a configuration of a memory device according to an embodiment of the present disclosure.

FIG. 2 is a circuit diagram illustrating a configuration of a memory cell array of FIG. 1 according to example embodiments.

FIG. 3 is a circuit diagram illustrating a configuration of a memory cell array of FIG. 1 according to example embodiments.

FIGS. 4 and 5 illustrate configurations of a memory cell of FIG. 2.

FIG. 6 is distribution diagrams illustrating program states of a normal cell and an OTP cell according to example embodiments.

FIG. 7 is a distribution diagram illustrating a program state of an OTP cell according to example embodiments.

FIG. 8 is a diagram illustrating a configuration associated with a memory cell of FIG. 2.

FIG. 9 is a diagram illustrating a configuration of a driver of FIG. 1 according to example embodiments.

FIG. 10 is a flowchart illustrating an OTP write method according to an embodiment of the present disclosure.

FIGS. 11A to 11C illustrate write voltages used in the OTP write operation according to example embodiments.

FIG. 12 conceptually illustrates a change in an MTJ resistance value of an OTP cell during an OTP write operation according to an embodiment of the present disclosure.

FIG. 13 conceptually illustrates a change in an MTJ resistance value of an OTP cell during an OTP write operation according to an embodiment of the present disclosure.

FIG. 14 illustrates a configuration of a sensing circuit of FIG. 1 according to example embodiments.

FIG. 15 is a circuit diagram illustrating a configuration of a sensing circuit of FIG. 14 according to example embodiments.

FIG. 16 is a circuit diagram illustrating a modified configuration of a sensing circuit of FIG. 15 according to example embodiments.

FIG. 17 illustrates a configuration of a reference resistor of FIG. 16 according to example embodiments.

FIG. 18 is a circuit diagram illustrating a configuration of a sensing circuit of FIG. 14 according to example embodiments.

FIG. 19 is a graph illustrating a change in a level of a reference voltage according to a level of a clamping voltage of a sensing circuit of FIG. 18 according to example embodiments.

FIG. 20 is a graph illustrating a difference between voltages developed depending on timings of a sense amplifier enable signal of a sensing circuit of FIG. 14 according to example embodiments.

FIG. 21 is a circuit diagram illustrating a modified configuration of a sensing circuit of FIG. 15 according to example embodiments.

FIG. 22 illustrates a configuration of a sensing circuit of FIG. 1 according to example embodiments.

FIG. 23 is a diagram illustrating a system to which a memory device according to an embodiment of the present disclosure is applied.

### DETAILED DESCRIPTION

Below, embodiments of the present disclosure will be described in detail and clearly to such an extent that an ordinary one in the art easily carries out the present disclosure.

In the detailed description, components which are described with reference to the terms “unit”, “module”, “block”, “˜er or ˜or”, etc. and function blocks which are illustrated in drawings will be implemented in the form of software or hardware or a combination thereof. For example, the software may include a machine code, firmware, an embedded code, and application software. For example, the hardware may include an electrical circuit, an electronic circuit, a processor, a computer, an integrated circuit, integrated circuit cores, a pressure sensor, an inertial sensor, a microelectromechanical system (MEMS), a passive element, or a combination thereof.

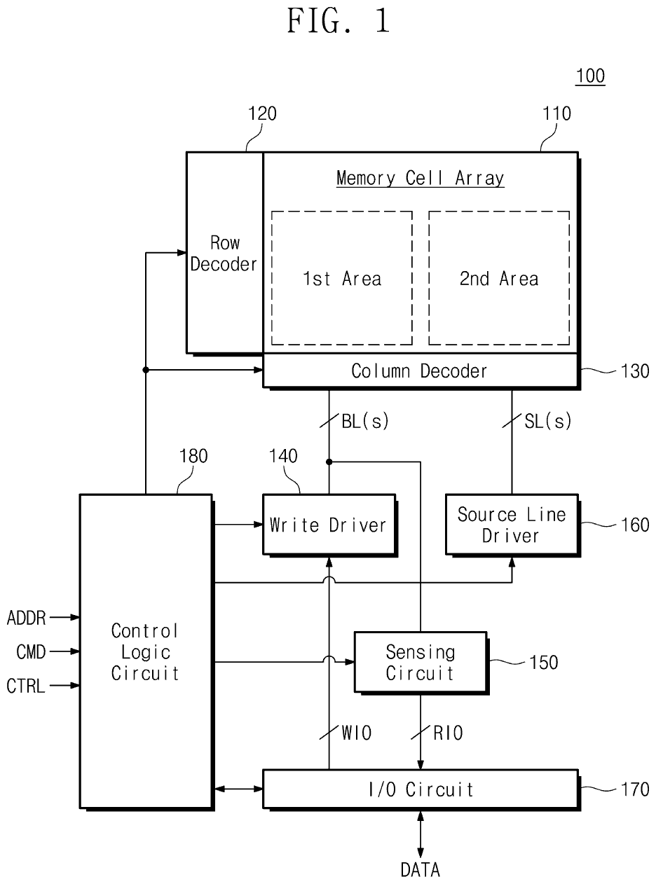

FIG. 1 is a diagram illustrating a configuration of a memory device according to an embodiment of the present disclosure.

A memory device 100 may include a memory cell array 110, a row decoder 120, a column decoder 130, a write driver 140, a sensing circuit 150, a source line driver 160, an input/output circuit 170, and a control logic circuit 180.

The memory cell array 110 may include a plurality of memory cells each configured to store data. For example, each memory cell may include a variable resistance element, and a value of data stored therein may be determined based on a resistance value of the variable resistance element. For example, each memory cell may include a magneto-resistive RAM (MRAM) cell, a spin transfer torque MRAM (STT-MRAM) cell, a spin-orbit torque MRAM (SOT-MRAM) cell, a phase-change RAM (PRAM) cell, a resistive RAM (ReRAM) cell, etc. In the specification, below, the description will be given under the assumption that each memory cell includes an STT-MRAM cell.

The memory cells constituting the memory cell array 110 may be connected to source lines SL, bit lines BL, and word lines. For example, memory cells arranged along a row may be connected in common to a word line corresponding to the row, and memory cells arranged along a column may be connected in common to a source line and a bit line corresponding to the column.

The memory cell array 110 may include a first area and a second area. The first area may include normal cells storing user data. In the normal cells, a program state may be determined by using a first reference resistance. The second area may include a one time programmable (OTP) memory that includes OTP cells. In the OTP cells, a program state may be determined by using a second reference resistance whose value is smaller than that of the first reference resistance. Information about operations and/or management of the memory device 100 may be programmed in the OTP cells. For example, information about a fail address of the memory cell array 110, information about internal voltages (e.g., a program voltage and a read voltage) of the memory device 100, etc. may be programmed in the OTP cells.

Meanwhile the OTP cell may have a very small MTJ resistance by programming the OTP cell with a high voltage such that the breakdown is caused. Below, an operation of causing the breakdown in the OTP cell by performing programming for the OTP cell by using the high voltage is referred to as an “OTP write operation”. In general, to prevent the high voltage from being applied to the memory cells of the first area, the first area and the second area may be formed in separate memory cell arrays. However, according to the present disclosure, the normal cells of the first area and the OTP cells of the second area may be formed in one memory cell array, and the influence on the normal cells of the first area may be minimized even though there is performed the OTP write operation by using the high voltage. According to the above description, as the deterioration of the normal cell is prevented, the reliability of a memory device may be improved.

The row decoder 120 may select (or drive) a word line connected to a memory cell targeted for the read operation or the program operation under control of the control logic circuit 180. The row decoder 120 may provide the selected word line with a driving voltage received from the control logic circuit 180.

The column decoder 130 may select the bit line BL and/or the source line SL connected to the memory cell targeted for the read operation or the program operation under control of the control logic circuit 180.

In the program operation, the write driver 140 may drive a program voltage (or a write current) for storing write data in a memory cell selected by the row decoder 120 and the column decoder 130. For example, in the program operation of the memory device 100, the write driver 140 may store the write data in the selected memory cell by controlling a voltage of the bit line BL based on the write data provided from the input/output circuit 170 through a write input/output line WIO.

In the read operation, the sensing circuit 150 may sense a signal output through the bit line BL and may determine a value of data stored in the selected memory cell. The sensing circuit 150 may be connected to the column decoder 130 through the bit line BL and may be connected to the input/output circuit 170 through a read input/output line RIO. The sensing circuit 150 may output the sensed read data to the input/output circuit 170 through the read input/output line RIO.

The source line driver 160 may drive the source line SL to a target voltage level under control of the control logic circuit 180. For example, the source line driver 160 may be provided with a voltage for driving the source line SL from the control logic circuit 180. For example, a value of a voltage applied from the source line driver 160 to the source line SL when the program operation is performed such that a memory cell has a great resistance value (e.g., an anti-parallel state) may be different from a value of a voltage applied from the source line driver 160 to the source line SL when the program operation is performed such that a memory cell has a small resistance value (e.g., a parallel state).

In the program operation, the input/output circuit 170 may receive write data “DATA” from the outside and may provide the received write data to the write driver 140. In the read operation, the input/output circuit 170 may read data from the memory cell array 110 and may output the read data to the outside as read data “DATA”.

The control logic circuit 180 may receive a command CMD, an address ADDR, and a control signal CTRL from the outside. The control logic circuit 180 may control the components of the memory device 100, based on the command CMD, the address ADDR, and the control signal CTRL. For example, the control logic circuit 180 may control the row decoder 120 and the column decoder 130, and thus, a target memory cell on which the program operation or the read operation is to be performed may be selected.

In an embodiment, the control logic circuit 180 may generate signals for controlling the write driver 140 and the source line driver 160 based on the control signal CTRL. The write driver 140 and the source line driver 160 may generate a program voltage (or switching current) of a desired level based on the signals received from the control logic circuit 180. The control logic circuit 180 may control a value of the reference resistance, which is used to determine a program state of a normal cell or an OTP cell, based on the control signal CTRL. The control signal CTRL may include information about the value of the reference resistance for determining the program state of the normal cell and information about the value of the reference resistance for determining the program state of the OTP cell.

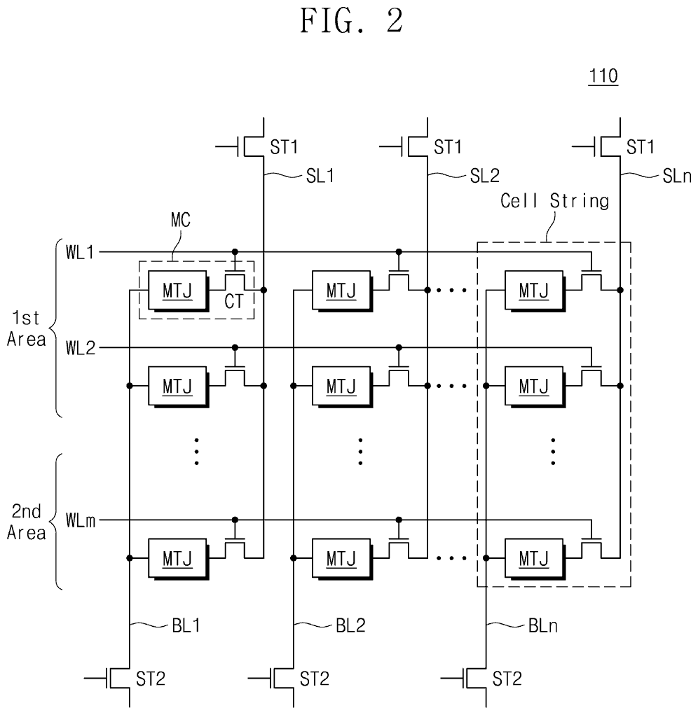

FIG. 2 is a circuit diagram illustrating a configuration of the memory cell array 110 of FIG. 1 according to example embodiments.

Select transistors ST1 and ST2 among components illustrated in FIG. 2 may constitute the column decoder 130 (refer to FIG. 2) and are illustrated together with the memory cell array 110 to represent the connection relationship with the memory cell array 110.

The memory cell array 110 may include a plurality of memory cells arranged along row and column directions. A memory cell MC may include a magnetic tunnel junction (MTJ) element and a cell transistor CT. As the MTJ element of the memory cell MC is programmed to have a specific resistance value, data corresponding to the specific resistance value may be stored in the memory cell MC. A cell string may include a plurality of memory cells which are connected in common to one bit line and one source line.

The plurality of memory cells may be connected to word lines WL1 to WLm, m is a natural number of 2 or greater, bit lines BL1 to BLn, and source lines SL1 to SLn, n is a natural number of 2 or greater. A first end of the MTJ element may be connected to the first bit line BL1, and a second end of the MTJ element may be connected to a first end of the cell transistor CT. A second end of the cell transistor CT may be connected to the first source line SL1, and a gate electrode of the cell transistor CT may be connected to the first word line WL1. The source lines SL1 to SLn may be respectively connected to the select transistors ST1, and the bit lines BL1 to BLn may be respectively connected to the select transistors ST2.

For example, the memory cell array 110 may include the first area and the second area. The first area may include normal cells where user data are stored. The second area may include OTP cells where data necessary to manage a memory device are stored.

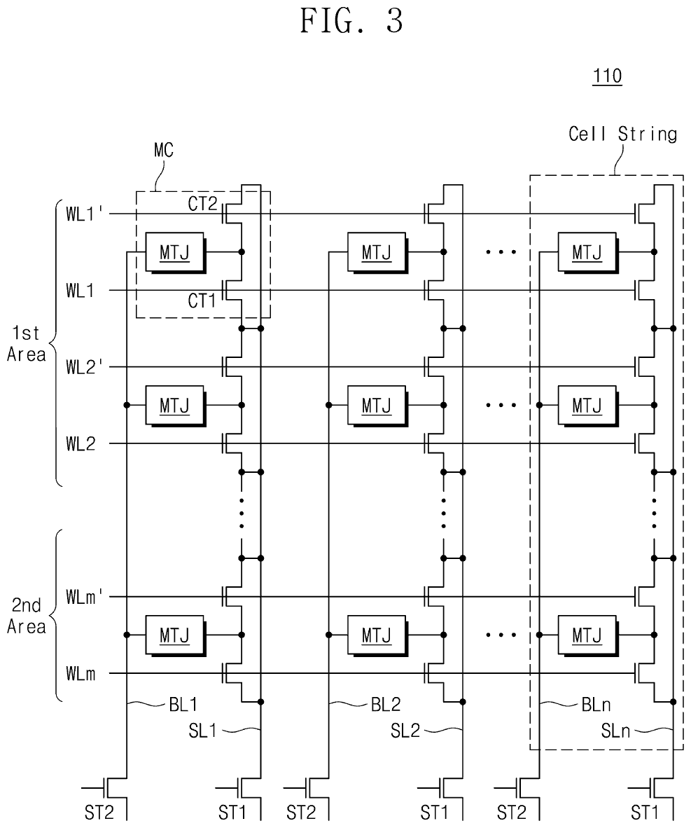

FIG. 3 is a circuit diagram illustrating a configuration of the memory cell array 110 of FIG. 1 according to example embodiments.

Select transistors ST1 and ST2 among components illustrated in FIG. 3 may constitute the column decoder 130 (refer to FIG. 1) and are illustrated together with the memory cell array 110 to represent the connection relationship with the memory cell array 110.

The memory cell array 110 may include a plurality of memory cells arranged along row and column directions. A memory cell MC may include a magnetic tunnel junction (MTJ) element and two cell transistors CT1 and CT2. A cell string may include a plurality of memory cells which are connected in common to one bit line and one source line.

The memory cell MC may have a structure in which the two cell transistors CT1 and CT2 share one MTJ element. A first end of the MTJ element may be connected to the first bit line BL1, and a second end of the MTJ element may be connected to first ends of the cell transistors CT1 and CT2. Second ends of the cell transistors CT1 and CT2 may be connected to the first source line SL1. A gate electrode of the first cell transistor CT1 may be connected to a first word line WL1, and a gate electrode of the second cell transistor CT2 may be connected to a first sub-word line WL1′. Each of the cell transistors CT1 and CT2 may be turned on or turned off by a signal (or a voltage) provided through a word line or a sub-word line.

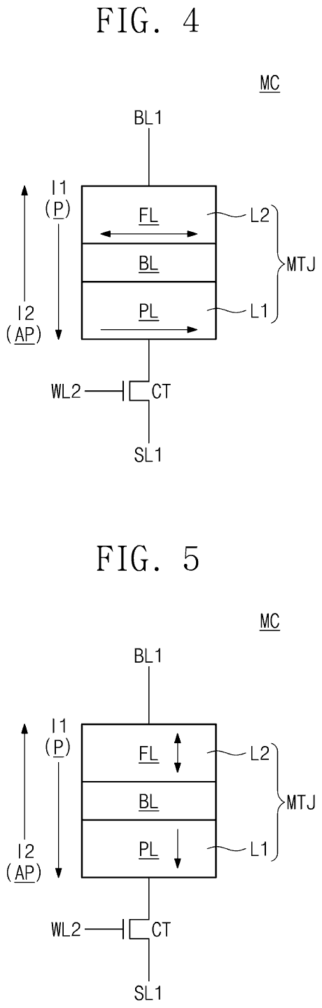

FIGS. 4 and 5 illustrate configurations of a memory cell of FIG. 2.

Referring to FIGS. 4 and 5, an MTJ element may include a first magnetic layer L1, a second magnetic layer L2, and a barrier layer BL (or a tunneling layer) interposed therebetween. The barrier layer BL may include at least one of a magnesium (Mg) oxide layer, a titanium (Ti) oxide layer, an aluminum (Al) oxide layer, a magnesium-zinc (Mg—Zn) oxide layer, and magnesium-boron (Mg—B) oxide layer, or a combination thereof. Each of the first magnetic layer L1 and the second magnetic layer L2 may include at least one magnetic layer.

In detail, the first magnetic layer L1 may include a reference layer (e.g., a pinned layer PL) having a magnetization direction fixed (or pinned) in a specific direction, and the second magnetic layer L2 may include a free layer FL having a magnetization direction changeable to be parallel or anti-parallel to the magnetization direction of the reference layer. However, the case where the first magnetic layer L1 includes the reference layer PL and the second magnetic layer L2 includes the free layer FL is illustrated in FIGS. 4 and 5 as an example, but the present invention is not limited thereto. For example, unlike the example illustrated in FIGS. 4 and 5, the first magnetic layer L1 may include a free layer, and the second magnetic layer L2 may include a pinned layer.

In an embodiment, as illustrated in FIG. 4, magnetization directions may be mostly parallel to an interface of the barrier layer BL and the first magnetic layer L1. In this case, each of the reference layer and the free layer may include a ferromagnetic material. For example, the reference layer may further include an anti-ferromagnetic material for pinning a magnetization direction of the ferromagnetic material.

In an embodiment, as illustrated in FIG. 5, magnetization directions may be mostly perpendicular to the interface of the barrier layer BL and the first magnetic layer L1. In this case, each of the reference layer and the free layer may include at least one of a perpendicular magnetic material (e.g., CoFeTb, CoFeGd, or CoFeDy), a perpendicular magnetic material with an L10 structure, a CoPt-based material with a hexagonal-close-packed-lattice structure, and a perpendicular magnetic structure, or a combination thereof. The perpendicular magnetic material with the L10 structure may include at least one of FePt with the L10 structure, FePd with the L10 structure, CoPd with the L10 structure, or CoPt with the L10 structure, or a combination thereof. The perpendicular magnetic structure may include magnetic layers and non-magnetic layers which are alternately and repeatedly stacked. For example, the perpendicular magnetic structure may include at least one of (Co/Pt) n, (CoFe/Pt) n, (CoFe/Pd) n, (Co/Pd) n, (Co/Ni) n, (CoNi/Pt) n, (CoCr/Pt) n, and (CoCr/Pd) n (n being the number of stacked layers), or a combination thereof. Here, the thickness of the reference layer may be greater than the thickness of the free layer, or a coercive force of the reference layer may be greater than a coercive force of the free layer.

In an embodiment, when a voltage of a relatively high level is applied to the bit line BL1 and a voltage of a relatively low level is applied to the source line SL1, a write current I1 may flow. In this case, the magnetization direction of the second magnetic layer L2 may be the same as the magnetization direction of the first magnetic layer L1, and thus, the MTJ element may have a low resistance value (i.e., a parallel state). When the MTJ element is in the parallel state, the memory cell MC may be regarded as storing data of a first value (e.g., logic “0”).

In contrast, when a voltage of a relatively high level is applied to the source line SL1 and a voltage of a relatively low level is applied to the bit line BL1, a write current I2 may flow. In this case, the magnetization direction of the second magnetic layer L2 may be opposite to the magnetization direction of the first magnetic layer L1, and thus, the MTJ element may have a great resistance value (i.e., an anti-parallel state). When the MTJ element is in the anti-parallel state, the memory cell MC may be regarded as storing data of a second value (e.g., logic “1”).

For example, when there is performed the OTP write operation on the memory cell of FIG. 4 or 5 by using a voltage whose level is higher than that of a voltage for programming the memory cell to the parallel state or the anti-parallel state, the barrier layer BL may be broken down due to a high voltage applied to a bit line and/or a source line. In this case, the first magnetic layer L1 and the second magnetic layer L2 may be electrically connected, thereby causing the decrease in the resistance value of the MTJ element. A memory cell, which has a low MTJ resistance value due to the breakdown, from among the OTP cells of the second area of the memory cell array 110 (refer to FIG. 1) may be regarded as storing data of the first value (e.g., logic “0”). In contrast, a memory cell, which does not experience the breakdown, that is, has a high MTJ resistance value, from among the OTP cells of the second area of the memory cell array 110 (refer to FIG. 1) may be regarded as storing data of the second value (e.g., logic “1”).

Only one cell transistor CT is illustrated in FIGS. 4 and 5, but the components illustrated in FIGS. 4 and 5 may also be applied to the memory cell of FIG. 3. In this case, the cell transistors CT1 and CT2 may be connected to the first end of the MTJ element. The basic principle, operation, etc. of the MTJ element may be identically applied to the memory cell of FIG. 3 except that a current path changes depending on a cell transistor turned on from among the cell transistors CT1 and CT2.

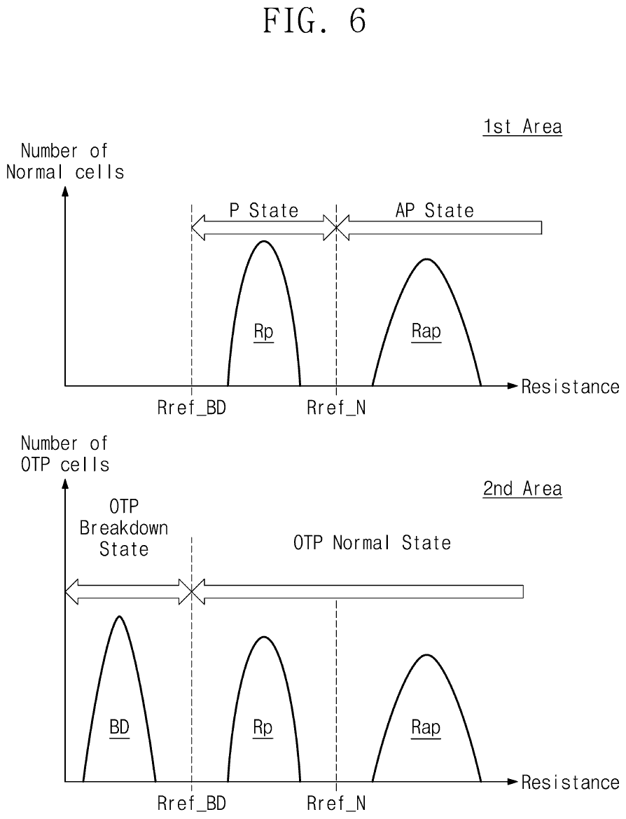

FIG. 6 is distribution diagrams illustrating program states of a normal cell and an OTP cell according to example embodiments.

Like the description given with reference to FIGS. 4 and 5, the normal cells may be programmed to a parallel state “P” or an anti-parallel state AP depending on the program voltage. Program states of the normal cells may be distinguished by a reference resistance Rref_N. Normal cells programmed to the parallel state “P” may be distributed over relatively low resistance values and may correspond to logic “0”. For example, a resistance value of a normal cell programmed to the parallel state “P” may be greater than a value of a reference resistance Rref_BD and may be smaller than a value of the reference resistance Rref_N. Normal cells programmed to the anti-parallel state AP may be distributed over relatively high resistance values and may correspond to logic “1”. For example, a resistance value of a normal cell programmed to the anti-parallel state AP may be greater than the value of the reference resistance Rref_N.

Meanwhile, the OTP cells may have an OTP breakdown state or an OTP normal state (e.g., non-breakdown state) depending on the program voltage. For example, the OTP cells in the non-breakdown state may be programmed to the parallel state “P” or the anti-parallel state AP, or may be remained fab-out. Program states of the OTP cells may be distinguished by the reference resistance Rref_BD. OTP cells programmed to the OTP breakdown state may be distributed over very low resistance values and may correspond to logic “0”. For example, a resistance value of an OTP cell programmed to the OTP breakdown state may be smaller than the value of the reference resistance Rref_BD. OTP cells programmed to the OTP normal state may be distributed over relatively high resistance values and may correspond to logic “1”. OTP cells programmed to the OTP normal state may mean memory cells, which do not experience the breakdown, from among the memory cells of the second area of the memory cell array 110 (refer to FIG. 1) (i.e., memory cells having the parallel state “P” or the anti-parallel state AP). Memory cells programmed to the OTP normal state may correspond to logic “1”. For example, a resistance value of an OTP cell programmed to the OTP normal state may be greater than the value of the reference resistance Rref_BD.

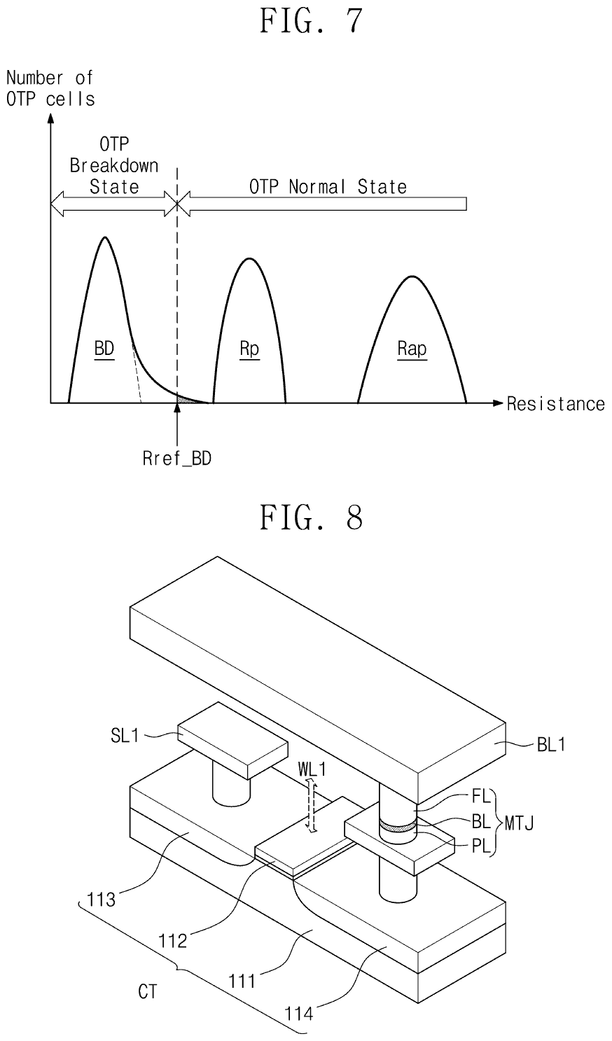

FIG. 7 is a distribution diagram illustrating a program state of an OTP cell according to example embodiments.

A distribution diagram corresponding to the case where the OTP write operation on the OTP cells of the second area of the memory cell array 110 (refer to FIG. 1) is ideally performed is the same as the distribution diagram of FIG. 6 above. However, due to various causes, the distribution diagram of the OTP cells having the OTP breakdown state may have a tail. For example, when a voltage or a current is not sufficient during the OTP write operation, the breakdown may not be caused, resulting in a write fail. Alternatively, even though the breakdown is caused during the OTP write operation, a perfect electrical connection between the first magnetic layer L1 and the second magnetic layer L2 of FIG. 4 may not be made; in this case, an MTJ resistance value may not be decreased as much as a desired value. This may mean that the MTJ resistance value of the OTP breakdown state and the MTJ resistance value of the OTP normal state become close, that is, the read fail occurs during the read operation.

FIG. 8 is a diagram illustrating a configuration associated with a memory cell of FIG. 2.

The cell transistor CT may include a body substrate 111, a gate electrode 112, and junctions 113 and 114. The junction 113 may be formed on the body substrate 111 and may be connected to the source line SL1. The junction 114 may be formed on the body substrate 111 and may be connected to the bit line BL1 through the MTJ element. The gate electrode 112 may be formed on the body substrate 111 between the junctions 113 and 114 and may be connected to the word line WL1. Meanwhile, the configuration of FIG. 8 is provided as an example. Like the embodiment described with reference to FIG. 3, when two cell transistors share one MTJ element, a modified version of the configuration illustrated in FIG. 3 may be adopted.

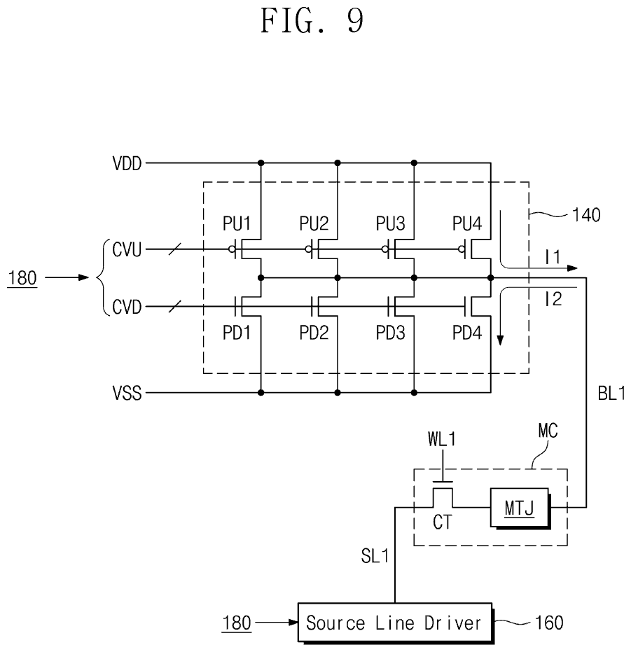

FIG. 9 is a diagram illustrating a configuration of a driver of FIG. 1 according to example embodiments. When the memory cell MC is the normal cell, the write driver 140 may program the memory cell MC to the parallel state “P” or the anti-parallel state AP. When the memory cell MC is the OTP cell, the write driver 140 may program the memory cell MC to the OTP breakdown state or the OTP normal state.

The write driver 140 may include pull-up transistors PU1 to PU4 and pull-down transistors PD1 to PD4. However, the present invention is not limited thereto. For example, the number of pull-up transistors may be less than or greater than 4, and the number of pull-down transistors may be less than or greater than 4. The pull-up transistors PU1 to PU4 may be connected between the first bit line BL1 and a first power supply voltage VDD. The pull-down transistors PD1 to PD4 may be connected between the first bit line BL1 and a second power supply voltage VSS. For example, a level of the first power supply voltage VDD may be higher than a level of the second power supply voltage VSS, and a level of a voltage of the first source line SL1 may be between the level of the first power supply voltage VDD and the level of the second power supply voltage VSS. In some examples, the level of a voltage of the first source line SL1 may be the level of the first power supply voltage VDD or the level of the second power supply voltage VSS. For example, the power supply voltages VDD and VSS may be provided from a voltage generator (not illustrated).

The write driver 140 may be connected to the memory cell MC through the first bit line BL1 selected by the column decoder 130 (refer to FIG. 1). In an embodiment, an additional driver which is implemented to be substantially the same as the write driver 140 may be provided for each of bit lines different from the first bit line BL1. However, for brevity of illustration, the descriptions associated with the additional drivers may be omitted.

The control logic circuit 180 may generate code values CVU and CVD for controlling the write driver 140. The code values CVU and CVD may be based on a mapping table which defines a value of a voltage for the normal write operation of the normal cell and/or a value of a voltage for the OTP write operation of the OTP cell. The code value CVU and the code value CVD may be implemented with a single code value or may be provided separately. An embodiment where the first code value CVU and the second code value CVD are provided as separate code values is illustrated in FIG. 9.

Each of the pull-up transistors PU1 to PU4 may be turned on or turned off based on the first code value CVU. For example, when each of the pull-up transistors PU1 to PU4 is implemented with a P-channel metal oxide semiconductor field effect transistor (P-type MOSFET), each of the pull-up transistors PU1 to PU4 may be turned on in response to a bit of logic “0” of the first code value CVU and may be turned off in response to a bit of logic “1” of the first code value CVU.

Each of the pull-down transistors PD1 to PD4 may be turned on or turned off based on the second code value CVD. For example, when each of the pull-down transistors PD1 to PD4 is implemented with an N-channel MOSFET (N-type MOSFET), each of the pull-down transistors PD1 to PD4 may be turned on in response to a bit of logic “1” of the second code value CVD and may be turned off in response to a bit of logic “0” of the second code value CVD. However, the configuration of the write driver 140 of FIG. 9 is provided only as an example and may be changed or modified to be different from the configuration illustrated in FIG. 9.

The turned-on transistors may provide a path for the write current I1 or I2. Accordingly, the pull-up transistors PU1 to PU4 and the pull-down transistors PD1 to PD4 may drive the write current I1 or I2 based on the first code value CVU and the second code value CVD.

For example, when one or more of the pull-up transistors PU1 to PU4 are turned on and the pull-down transistors PD1 to PD4 are turned off, a voltage of the first bit line BL1 may be pulled up to the first power supply voltage VDD. In this case, the write current I1 may be provided from the first bit line BL1 to the first source line SL1.

In contrast, when the pull-up transistors PU1 to PU4 are turned off and one or more of the pull-down transistors PD1 to PD4 are turned on, a voltage of the first bit line BL1 may be pulled down to the second power supply voltage VSS. In this case, the write current I2 may be provided from the first source line SL1 to the first bit line BL1. A data state of the memory cell MC may depend on the write current I1 or I2.

The number of turned-on transistors among the pull-up transistors PU1 to PU4 may change based on bits of the first code value CVU. The number of turned-on transistors among the pull-down transistors PD1 to PD4 may change based on bits of the second code value CVD. The intensities of the write currents I1 and I2 may change depending on the number of turned-on transistors.

As the number of turned-on transistors increases, the intensity of the write currents I1 and I2 may increase. The intensities of the write currents I1 and I2 may correspond to a sum of intensities of currents driven by turned-on transistors. Accordingly, the intensities of the write currents I1 and I2 may be adjusted based on the first code value CVU and the second code value CVD.

According to the above method, the write driver 140 may be configured to drive write currents with different values. Values of the write currents I1 and I2 flowing through the memory cell MC may be adjusted to have one of different values provided by the write driver 140.

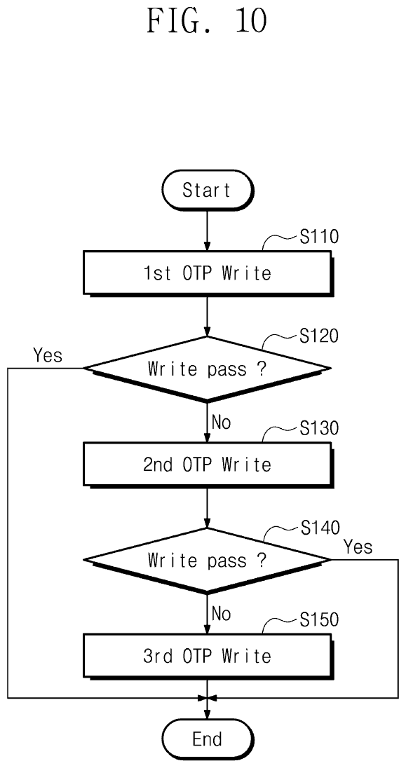

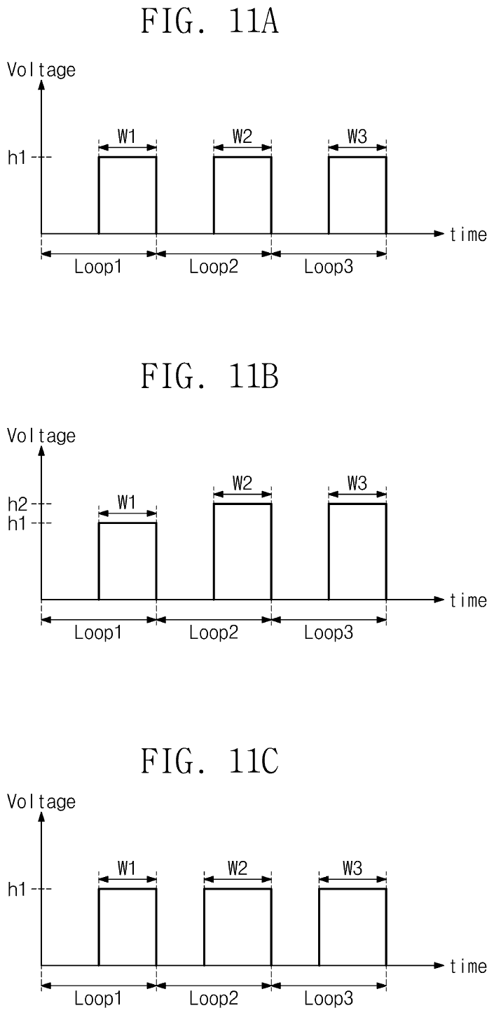

FIG. 10 is a flowchart illustrating an OTP write method according to an embodiment of the present disclosure. FIGS. 11A to 11C illustrate write voltages used in the OTP write operation of the present disclosure. Below, the OTP write method of the present disclosure will be described with reference to FIGS. 10 and 11A to 11C together.

In operation S110, a first OTP write operation may be performed. The control logic circuit 180 (refer to FIG. 1) may control the write driver 140 (refer to FIG. 1) and the source line driver 160 (refer to FIG. 1), and the write driver 140 and the source line driver 160 may generate a write voltage (or current) of a desired value. In an embodiment, the desired value may mean a write voltage (or current) which allows the OTP cell to have an MTJ resistance value which is smaller than or equal to a value of the reference resistance Rref_BD. In an embodiment, the first OTP write operation may correspond to a first loop Loop1, the value of the write voltage may be “h1”, and the duration of the write voltage may be “W1” (refer to FIG. 11A).

In operation S120, an operation of verifying whether the first OTP write operation succeeds may be performed. For example, the verify operation may be similar to the read operation. Accordingly, the verify operation may be referred to as a “verify read operation”. For example, to determine whether the OTP write operation on the OTP cell succeeds, a reference resistance (e.g., Rref_BD of FIG. 6) may be used. However, there may be OTP cells experiencing the write fail due to the failure of the breakdown, a write voltage (or current) of an insufficient value, etc.

In operation S130, a second OTP write operation may be performed. The second OTP write operation may refer to a write operation on the OTP cells determined in operation S120 as experiencing the write fail. The write driver 140 and/or the source line driver 160 may generate the write voltage (or current) under control of the control logic circuit 180.

In an embodiment, the second OTP write operation may correspond to a second loop Loop2. In the second loop, the value of the write voltage may be “h1”, the duration of the write voltage may be “W2”. For example, the duration of “W2” may be identical to the duration of “W1” (refer to FIG. 11A). In an embodiment, the value of the write voltage may be “h2”, and the duration of the write voltage may be “W2”. In this case, “W1” may be identical in value to “W2”, and “h2” may be greater in value than “h1” (refer to FIG. 11B). In an embodiment, the value of the write voltage may be “h1”, and the duration of the write voltage may be “W2”. In this case, “W2” may be greater in value than “W1” (refer to FIG. 11C).

In operation S140, an operation of verifying whether the second OTP write operation succeeds may be performed. To determine whether the OTP write operation on the OTP cell succeeds, the reference resistance Rref_BD may be used. However, there may still be OTP cells experiencing the write fail due to the failure of the breakdown, a write voltage (or current) of an insufficient value, etc.

In operation S150, a third OTP write operation may be performed. The third OTP write operation may refer to an OTP write operation on OTP cells determined in operation S140 as experiencing the write fail. The write driver 140 and/or the source line driver 160 may generate the write voltage (or current) under control of the control logic circuit 180.

In an embodiment, the third OTP write operation may correspond to a third loop Loop3. In the third loop, the value of the write voltage may be “h1”, the duration of the write voltage may be “W3”. For example, the duration of “W3” may be identical to the duration of “W1” (refer to FIG. 11A). In an embodiment, the value of the write voltage may be “h2”, and the duration of the write voltage may be “W3”. In this case, “W1” may be identical in value to “W3”, and “h2” may be greater in value than “h1” (refer to FIG. 11B). In an embodiment, the value of the write voltage may be “h1”, and the duration of the write voltage may be “W3”. In this case, “W3” may be greater in value than “W1” (refer to FIG. 11C). In an embodiment, the third OTP write operation may include an operation of verifying whether the third OTP write operation succeeds.

Meanwhile, in the embodiment of FIG. 10, the description is given as the OTP write operation is performed three times, but the present invention is not limited thereto. For example, the OTP write operation may be executed two times or may be executed four times or more. In addition, one skilled in the art may understand that as the number of loops increases, the value of the write voltage and the duration of the write voltage are able to increase in various combinations/methods.

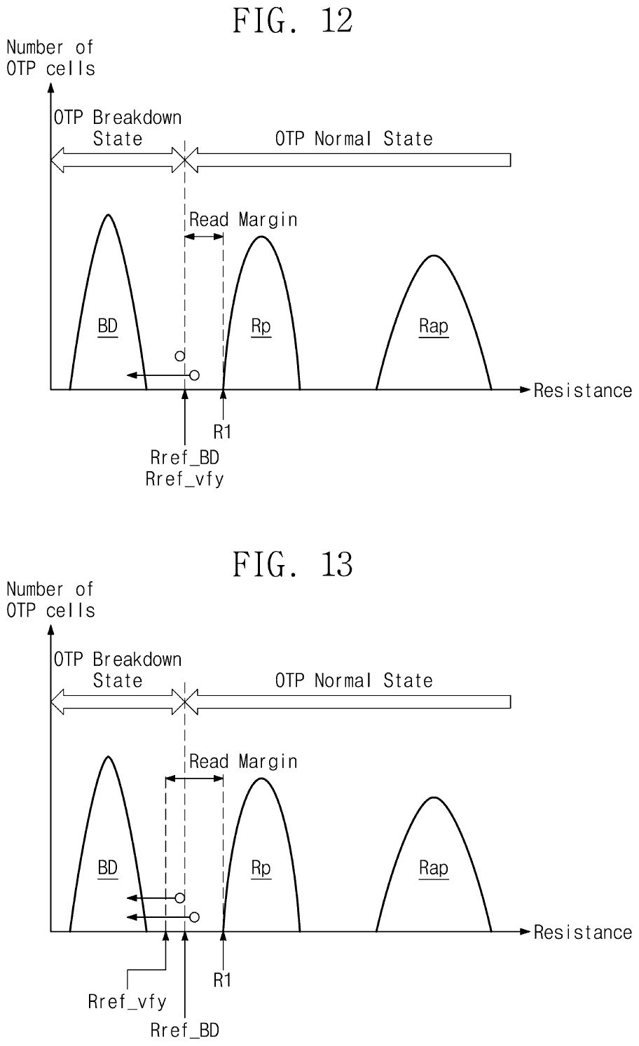

FIG. 12 conceptually illustrates a change in an MTJ resistance value of an OTP cell during an OTP write operation according to an embodiment of the present disclosure.

Referring to FIG. 12, “BD” indicates a resistance distribution of MTJ cells experiencing the breakdown, “Rp” indicates a resistance distribution of MTJ cells having the parallel state, and “Rap” indicates a resistance distribution of MTJ cells having the anti-parallel state.

The reference resistance Rref_BD may be a reference resistance for distinguishing the OTP breakdown state from the OTP normal state during the OTP read operation, and a reference resistance Rref_vfy may be a reference resistance which is used in an operation of verifying whether the OTP write operation succeeds. In an embodiment, the reference resistance Rref_BD may be identical in value to the reference resistance Rref_vfy.

Accordingly, during the verify operation which is performed during the OTP write operation, a memory cell whose MTJ resistance value is smaller than that of the reference resistance Rref_vfy may be determined as being program-passed and may be excluded from a target of an OTP re-write operation (e.g., S130 and S150 of FIG. 10). In contrast, during the verify operation which is performed during the OTP write operation, a memory cell whose MTJ resistance value is greater than that of the reference resistance Rref_vfy may be targeted for the OTP re-write operation.

Meanwhile, because the value of the reference resistance Rref_BD is approximately a median value of the upper limit of the resistance distribution BD and the lower limit of the resistance distribution Rp, resistance values of the MTJ cells having the OTP breakdown state may be regarded as being distributed between the lower limit of the OTP breakdown state and the value of the reference resistance Rref_BD. Accordingly, in the case of executing the OTP re-write operation on the write-failed OTP cells based on the reference resistance Rref_BD, the read margin of the memory device may be regarded as being between the reference resistance Rref_vfy and a lower limit R1 of the parallel state Rp. That is, the issue that the read margin for the OTP cells is approximately halved may occur.

FIG. 13 conceptually illustrates a change in an MTJ resistance value of an OTP cell during an OTP write operation according to an embodiment of the present disclosure.

Referring to FIG. 13, “BD” indicates a resistance distribution of MTJ cells experiencing the breakdown, “Rp” indicates a resistance distribution of MTJ cells having the parallel state, and “Rap” indicates a resistance distribution of MTJ cells having the anti-parallel state.

The reference resistance Rref_BD may be a reference resistance for distinguishing the OTP breakdown state from the OTP normal state during the OTP read operation, and the reference resistance Rref_vfy may be a reference resistance which is used in an operation of verifying whether the OTP write operation succeeds. In an embodiment, the reference resistance Rref_vfy may be smaller in value than the reference resistance Rref_BD.

Accordingly, during the verify operation which is performed during the OTP write operation, a memory cell whose MTJ resistance value is greater than the value of the reference resistance Rref_vfy may be determined as being program-failed; compared to the embodiment of FIG. 12, relatively more memory cells among memory cells being out of the intended distribution may be targeted for the OTP re-write operation. As a result, it is understood that the read margin of memory cells forming the distribution illustrated in FIG. 13 is greater than the read margin of memory cells forming the distribution illustrated in FIG. 12.

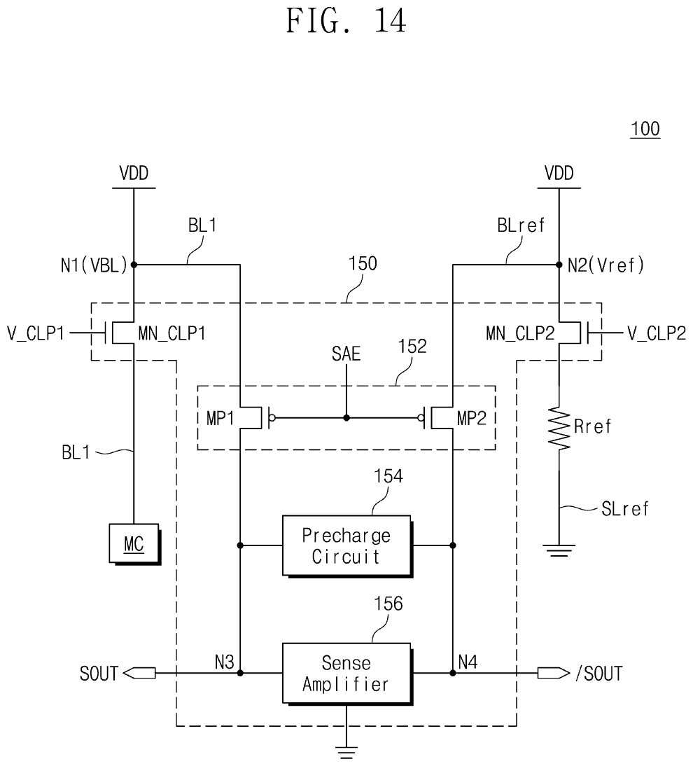

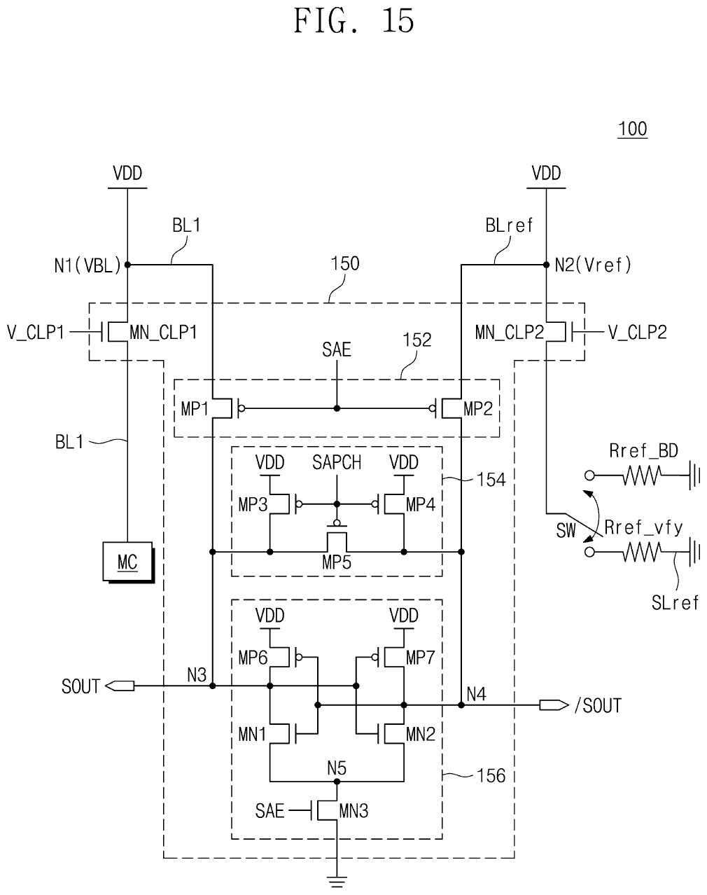

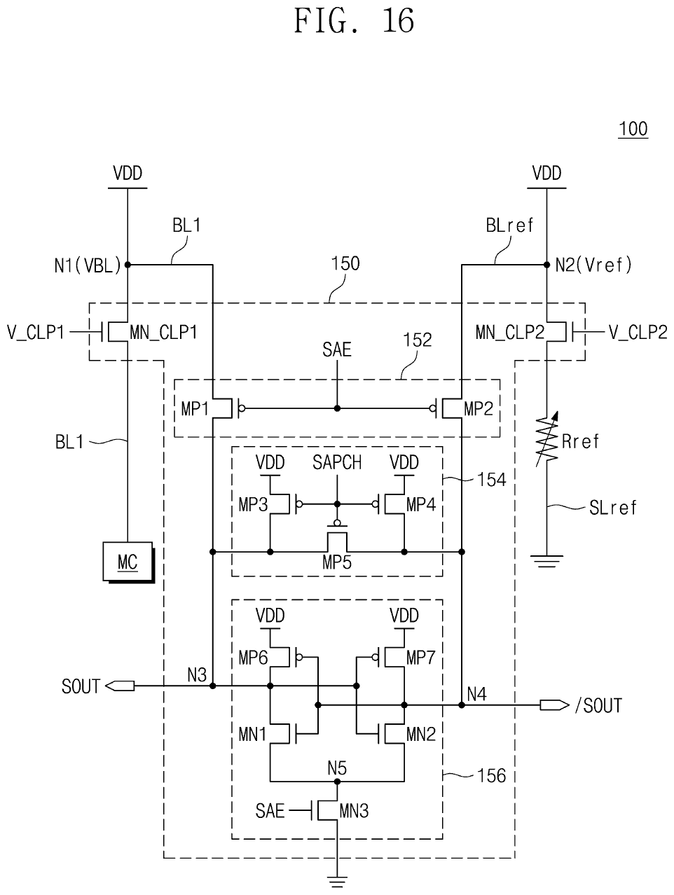

FIG. 14 illustrates a configuration of the sensing circuit 150 of FIG. 1 according to example embodiments.

The sensing circuit 150 may include a switching circuit 152, a precharge circuit 154, and a sense amplifier 156. For brevity of illustration, one sensing circuit corresponding to one bit line and a reference resistor Rref connected to a reference bit line BLref are illustrated in FIG. 14. The reference resistor Rref may correspond to the reference resistance. For example, a resistance value of the reference resistor Rref may be the same as the value of the reference resistance Rref_BD or the value of the reference resistance Rref_vfy described with reference to FIGS. 12 and 13. One OTP cell among normal cells and OTP cells connected to the bit line BL1 is illustrated. That is, the memory cell MC may be an OTP cell.

In response to a sense amplifier enable signal SAE, the switching circuit 152 may electrically connect the memory cell MC to the precharge circuit 154 and the sense amplifier 156 or may electrically disconnect the memory cell MC from the precharge circuit 154 and the sense amplifier 156. In response to the sense amplifier enable signal SAE, the switching circuit 152 may electrically connect the reference resistor Rref to the precharge circuit 154 and the sense amplifier 156 or may electrically disconnect the reference resistor Rref from the precharge circuit 154 and the sense amplifier 156.

In an embodiment, the switching circuit 152 may include PMOS transistors MP1 and MP2. The PMOS transistor MP1 may transfer a voltage (i.e., VBL) of a node N1, which is formed by a signal output from the memory cell MC, to the sense amplifier 156 through the bit line BL1. The PMOS transistor MP2 may transfer a voltage (i.e., Vref) of a node N2, which is formed by a signal output from the reference resistor Rref, to the sense amplifier 156 through the reference bit line BLref. For example, the transistors MP1 and MP2 may be referred to as “switching transistors”. However, the configuration of the switching circuit 152 of the present invention is not limited thereto. For example, the switching circuit 152 may further include various components for transferring the voltages VBL and Vref to the sense amplifier 156.

The precharge circuit 154 may pre-charge the bit line BL1 and the reference bit line BLref or may equalize the bit line BL1 and the reference bit line BLref with the same voltage. The precharge circuit 154 may include PMOS transistors and/or NMOS transistors, and may transfer a voltage (e.g., a power supply voltage) provided from the outside to the bit line BL1 and the reference bit line BLref.

The sense amplifier 156 may sense data stored in the memory cell MC by sensing a voltage difference of the bit line BL1 and the reference bit line BLref. For example, the sense amplifier 156 may be a differential type of sense amplifier. The sense amplifier 156 may output a sensing result as differential signals SOUT and/SOUT. The sense amplifier 156 may include PMOS transistors and NMOS transistors. For example, the sense amplifier 156 may output at least one of the differential signals SOUT and/SOUT to the input/output circuit 170 through the read input/output line RIO (refer to FIG. 1).

A clamping transistor MN_CLP1 may control a voltage level of the node N1 in response to a clamping voltage V_CLP1, and a clamping transistor MN_CLP2 may control a voltage level of the node N2 in response to a clamping voltage V_CLP2. In an embodiment, the clamping voltages V_CLP1 and V_CLP2 may be generated by an external voltage generator (not illustrated).

In an embodiment, in the case of determining data stored in the memory cell MC, when a level of the voltage VBL output through the bit line BL1 is higher than a level of the voltage Vref output through the reference bit line BLref, it may be determined that the memory cell MC stores data of a first value (i.e., “0” or “1”). In contrast, when a level of the voltage VBL output through the bit line BL1 is lower than a level of the voltage Vref output through the reference bit line BLref, it may be determined that the memory cell MC stores data of a second value (i.e., “1” or “0”). For example, the first value is opposite to the second value.

FIG. 15 is a circuit diagram illustrating a configuration of the sensing circuit of FIG. 14 according to example embodiments. In detail, the circuit diagram of FIG. 15 may be associated with the configuration for increasing the read margin, which is described with reference to FIG. 13.

The precharge circuit 154 may include transistors MP3, MP4, and MP5. The transistor MP3 may be connected between a node N3 and a terminal supplying the power supply voltage VDD. The transistor MP4 may be connected between a node N4 and the terminal supplying the power supply voltage VDD. The transistor MP5 may be connected between the node N3 and the node N4. The transistors MP3, MP4, and MP5 may operate in response to a sense amplifier precharge signal SAPCH such that the nodes N3 and N4 are precharged or equalized.

The sense amplifier 156 may be configured to sense a voltage difference of the bit line BL1 and the reference bit line BLref. In an embodiment, the sense amplifier 156 may be a sense amplifier of a voltage latch type. The sense amplifier 156 may include a first inverter composed of transistors MP6 and MN1 and a second inverter composed of transistors MP7 and MN2. An input terminal of the first inverter and an output terminal of the second inverter may be connected to each other, and an output terminal of the first inverter and an input terminal of the second inverter may be connected to each other. The output terminal of the first inverter and the input terminal of the second inverter may be connected to the node N3, and the output terminal of the second inverter and the input terminal of the first inverter may be connected to the node N4. Source terminals of the transistors MN1 and MN2 may be connected to a node N5.

A transistor MN3 may operate in response to the sense amplifier enable signal SAE. For example, the transistor MN3 may be turned on in response to the sense amplifier enable signal SAE having a logic high value, and thus, the node N5 may be grounded. In this case, a ground voltage may be provided to the source terminals of the transistors MN1 and MN2. The transistor MN3 may be turned off in response to the sense amplifier enable signal SAE having a logic low value, and thus, the node N5 may be floated. The transistor MN3 may be referred to as a “switching transistor” or “enable transistor”.

In an embodiment, a switch SW may connect a reference resistor Rref_BD to the clamping transistor MN_CLP2 during the OTP read operation and may connect the reference resistor Rref_vfy to the clamping transistor MN_CLP2 during the verify operation (e.g., S120 of FIG. 10). The reference resistor Rref_BD and the reference resistor Rref_vfy may correspond to the reference resistance Rref_BD and the reference resistance Rref_vfy, respectively. For example, the switch SW may perform a switching operation under control of the control logic circuit 180. As a result, a level of the voltage Vref of the node N2, which is formed when the reference resistor Rref_vfy is used during the verify operation, may be lower than a level of the voltage Vref of the node N2, which is formed when the reference resistor Rref_BD is used during the read operation.

As described above, the configuration of the voltage latch-type sense amplifier is illustrated in FIG. 15 as an example, but the configuration of the sense amplifier 156 of the present invention is not limited thereto. For example, the present invention may be applied to various latch-type sense amplifiers capable of determining a value stored in the memory cell MC by comparing the voltage VBL of the bit line, which is formed by the signal output from the memory cell MC, with the reference voltage Vref formed by the reference resistor Rref.

FIG. 16 is a circuit diagram illustrating a modified configuration of the sensing circuit of FIG. 15 according to example embodiments. In detail, a configuration of a sensing circuit 150 of FIG. 16 is the same as the configuration of the sensing circuit 150 of FIG. 15 except that the reference resistor Rref is a variable resistor. Thus, additional description may be omitted to avoid redundancy.

In an embodiment, the control logic circuit 180 (refer to FIG. 1) may control the reference resistor Rref such that a value of the reference resistor Rref is set to a value of the reference resistor Rref_BD (refer to FIG. 15) during the OTP read operation. Also, the control logic circuit 180 (refer to FIG. 1) may control the reference resistor Rref such that a value of the reference resistor Rref is set to a value of the reference resistor Rref_vfy (refer to FIG. 15) during the verify operation. As described above, the same effect as one of the reference resistors Rref_BD and Rref_vfy is selected by a switching operation may be obtained by adopting the reference resistor Rref.

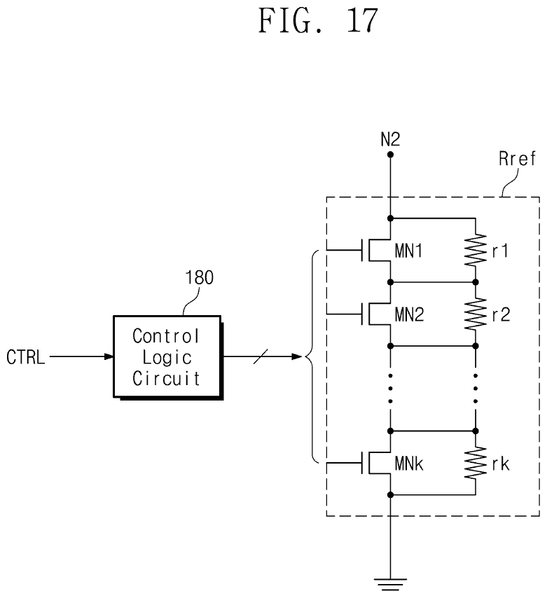

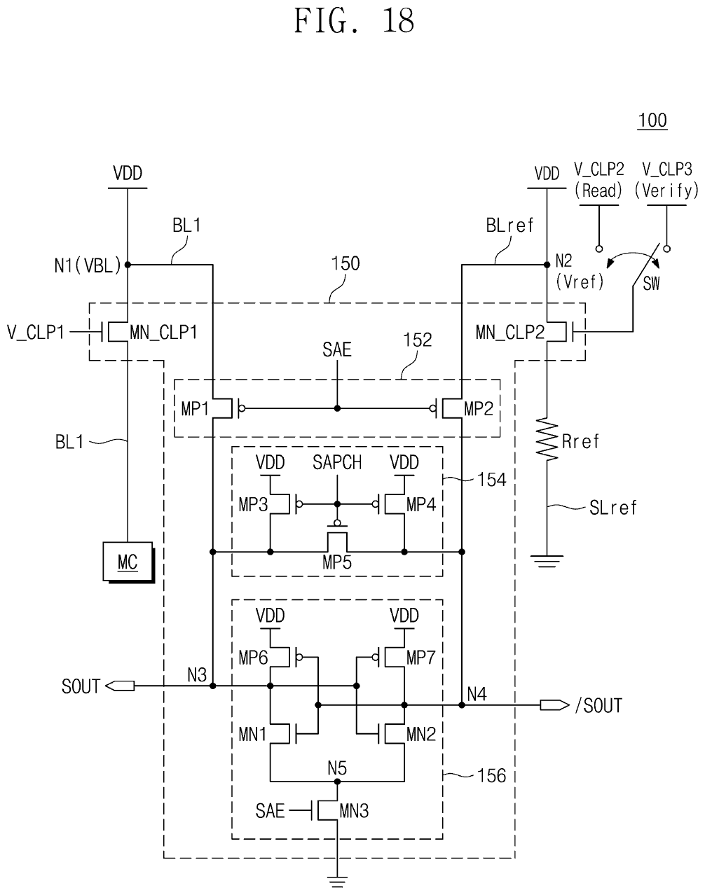

FIG. 17 illustrates a configuration of the reference resistor Rref of FIG. 16 according to example embodiments.

The reference resistor Rref may be configured such that a resistance value of the reference resistor Rref varies under control of the control logic circuit 180. For example, the control logic circuit 180 may control the reference resistor Rref based on the control signal CTRL including information about values of the reference resistors Rref_BD and Rref_vfy.

In an embodiment, the reference resistor Rref may include a plurality of transistors MN1 to MNk and a plurality of resistors r1 to rk, k is a natural number of 3 or greater. The plurality of transistors MN1 to MNk may be individually turned on or turned off under control of the control logic circuit 180. When a transistor is turned on, a current may flow from the second node N2 to a ground electrode; in this case, it may be regarded as no current flows through a resistor connected between opposite ends of the turned-on transistor. For example, when the transistor MN1 is turned off and the remaining transistors MN2 to MNk are turned on, a path of a current flowing from the second node N2 to the ground electrode may be “r1-MN2-, . . . ,-MNk”, and a value of the reference resistor Rref may be “r1”.

However, the configuration of the reference resistor Rref is not limited to the example illustrated in FIG. 17, and various configurations in which a resistance value is variable under control the control logic circuit 180 may be adopted.

FIG. 18 is a circuit diagram illustrating a configuration of the sensing circuit of FIG. 14 according to example embodiments. A sensing circuit 150 of FIG. 18 is mostly the same as the sensing circuit 150 of FIG. 15. However, the clamping transistor MN_CLP2 of the sensing circuit 150 of FIG. 18 may operate based on clamping voltages V_CLP2 and V_CLP3. The sensing circuit 150 of FIG. 18 may include the reference resistor Rref.

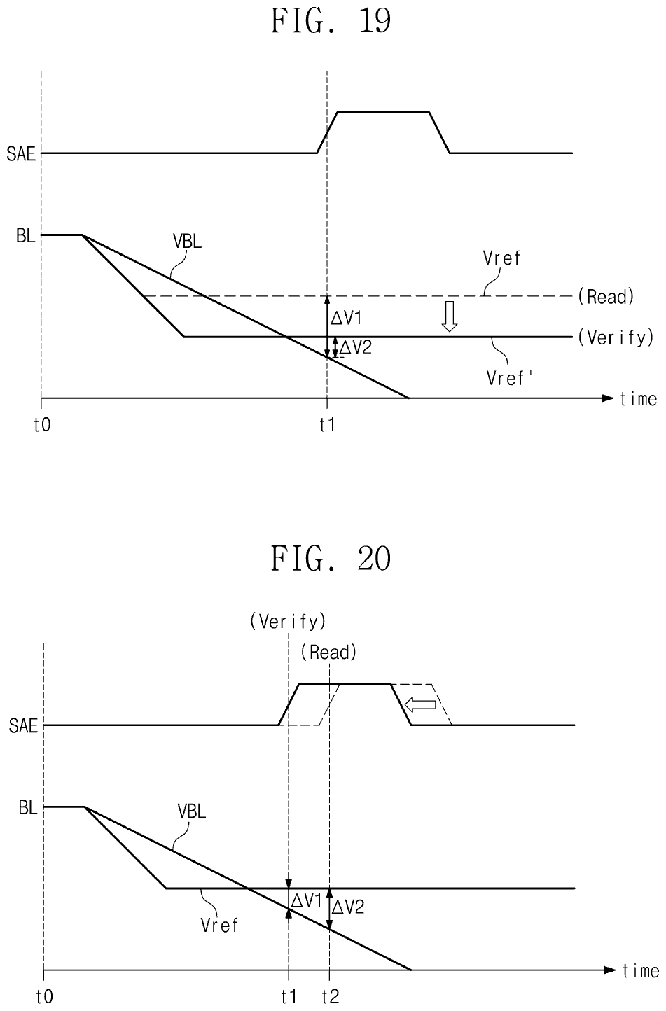

Referring to FIG. 18, the sensing circuit 150 may perform the read operation and the verify operation by using only one reference resistor Rref. The sensing circuit 150 may operate in response to the clamping voltage V_CLP2 during the OTP read operation and may operate in response to the clamping voltage V_CLP3 during the verify operation. A level of the clamping voltage V_CLP3 may be higher than a level of the clamping voltage V_CLP2. In an embodiment, a switch SW may provide the clamping voltage V_CLP2 to a gate of the clamping transistor MN_CLP2 during the OTP read operation and may provide the clamping voltage V_CLP3 to the gate of the clamping transistor MN_CLP2 during the verify operation (e.g., S120 of FIG. 10). For example, the switch SW may perform a switching operation under control of the control logic circuit 180. As a result, a level of a voltage Vref (refer to FIG. 19) of the node N2, which is formed when the clamping transistor MN_CLP2 is turned on during the verify operation, may be lower than a level of the voltage Vref of the node N2, which is formed when the clamping transistor MN_CLP2 is turned on during the OTP read operation.

As a result, the sensing circuit 150 of FIG. 18 may operate to be identical to the sensing circuit 150 of FIG. 15 in that the level of the node N2 formed during the verify operation is lower than the level of the node N2 formed during the read operation. Accordingly, even though the sensing circuit 150 of FIG. 18 is used, the read margin may be increased.

FIG. 19 is a graph illustrating a change in a level of a reference voltage according to a level of a clamping voltage of the sensing circuit of FIG. 18 according to example embodiments.

The bit line voltage VBL indicates a voltage of the bit line BL1 of FIG. 18, which is formed during the verify (or OTP read) operation. The reference voltage Vref indicates a voltage of the node N2, which is formed when the clamping transistor MN_CLP2 is turned on by the clamping voltage V_CLP2 during the read operation. The reference voltage Vref indicates a voltage of the node N2, which is formed when the clamping transistor MN_CLP2 is turned on by the clamping voltage V_CLP3 during the OTP verify operation.

At a time point t1 when the sense amplifier enable signal SAE is activated, a voltage difference between the reference voltage Vref and the voltage VBL of the bit line BL1 may be ΔV1. At the time point t1 when the sense amplifier enable signal SAE is activated, a voltage difference between the reference voltage Vref′ and the voltage VBL of the bit line may be ΔV2. The voltage difference ΔV2 may be smaller than the voltage difference ΔV1. For example, during the verify operation, the absolute value of a voltage which is developed on the reference bit line BLref when the clamping transistor MN_CLP2 is turned on by the clamping voltage V_CLP3 may be smaller than the absolute value of a voltage which is developed on the reference bit line BLref when the clamping transistor MN_CLP2 is turned on by the clamping voltage V_CLP2.

As a result, it is confirmed from the graph of FIG. 19 that the level of the node N2 formed during the verify operation is lower than the level of the node N2 formed during the read operation, and it is confirmed that it is possible to increase the OTP read margin even though the sensing circuit 150 of FIG. 18 is used.

FIG. 20 is a graph illustrating a difference between voltages developed depending on timings of the sense amplifier enable signal SAE of the sensing circuit of FIG. 14 according to example embodiments.

The bit line voltage VBL indicates a voltage of the bit line BL1 of FIG. 14, which is formed during the verify (or OTP read) operation. The reference voltage Vref indicates a voltage of the node N2, which is formed when the clamping transistor MN_CLP2 is turned on by the clamping voltage V_CLP2 during the OTP read operation or the verify operation.

In an embodiment, during the OTP read operation, the sense amplifier enable signal SAE may be activated at a time point t2, and a voltage difference between the reference voltage Vref and the voltage VBL of the bit line may be ΔV2 at the time point t2. During the verify operation, the sense amplifier enable signal SAE may be activated at the time point t1, and a voltage difference between the reference voltage Vref and the voltage VBL of the bit line may be ΔV1 at the time point t1.

According to the above operating method, when a timing when the sense amplifier enable signal SAE is activated is advanced during the verify operation, a voltage difference between the reference voltage Vref and the voltage VBL of the bit line is amplified in a state where the voltage VBL of the bit line is less developed. This indicates substantially the same effect as described with reference to FIG. 19, that is, as the voltage difference ΔV2 between the reference voltage Vref and the voltage VBL of the bit line is smaller than the difference ΔV1. That is, it is confirmed that even though the graph of FIG. 20 is used, the OTP read margin is increased.

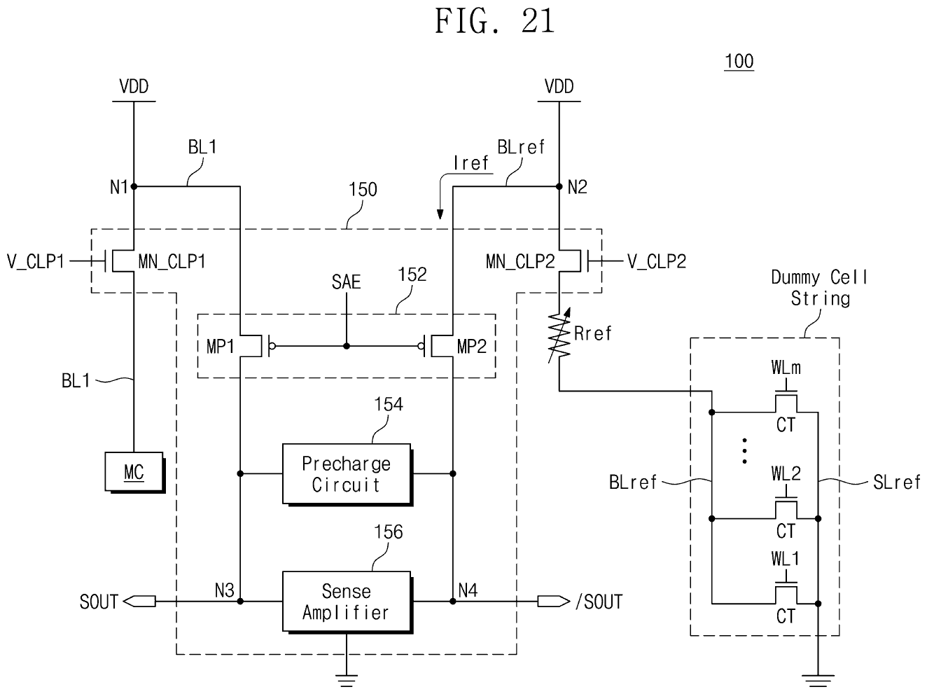

FIG. 21 is a circuit diagram illustrating a modified configuration of the sensing circuit of FIG. 15 according to example embodiments. In detail, a configuration of a sensing circuit 150 of FIG. 21 is the same as the configuration of the sensing circuit 150 of FIG. 15 except that the reference resistor Rref is a variable resistor and a dummy cell string is included. Thus, additional description may be omitted to avoid redundancy.

A first end of the reference resistor Rref may be connected to the node N2 through the clamping transistor MN_CLP2, and a second end thereof may be connected to the dummy cell string. The dummy cell string may include the reference bit line BLref, a reference source line SLref, and a plurality of cell transistors CT. Each gate of the plurality of cell transistors CT may be connected to a corresponding word line of word lines WL1 to WLm. The dummy cell string may be called a dummy area in that an MTJ element is not included therein.

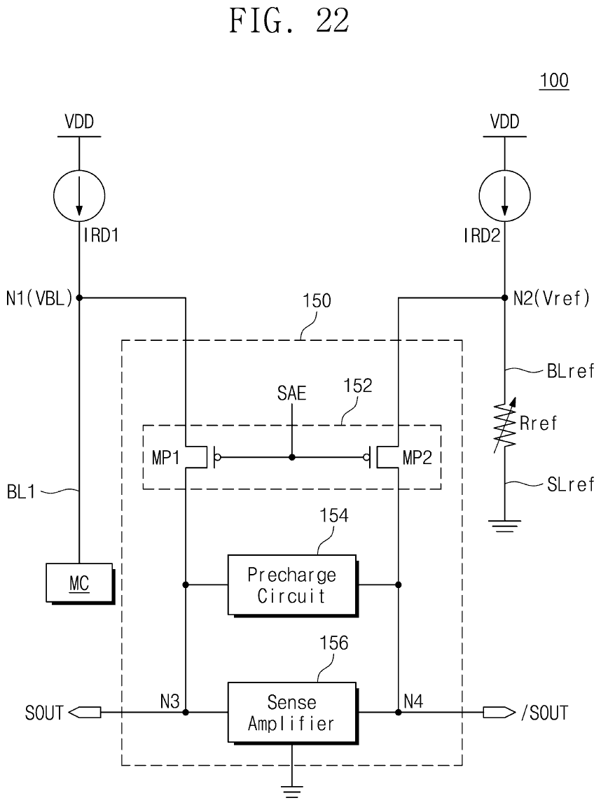

FIG. 22 illustrates a configuration of the sensing circuit 150 of FIG. 1 according to example embodiments.

Referring to FIG. 22, the sensing circuit 150 may be configured to read data stored in the memory cell MC connected to the bit line BL1. For example, the sensing circuit 150 may include the switching circuit 152, the precharge circuit 154, the sense amplifier 156, and a plurality of current sources. The sense amplifier 156 may be a sense amplifier of a voltage latch type.

A first read current IRD1 may be used to sense a voltage drop by a memory cell connected to the bit line BL1. For example, the first read current IRD1 may be input to an MTJ element of a selected memory cell which is connected to a selected word line and the bit line BL1. In this case, the voltage drop may be caused in the MTJ element connected to the word line.

A second read current IRD2 may be used to determine a voltage drop by the reference resistor Rref connected to the second node N2. For example, the second read current IRD2 may flow through the reference resistor Rref, and thus, a voltage drop may occur at the reference resistor Rref.

The sense amplifier 156 may sense a voltage difference of the first node N1 and the second node N2 and may amplify the sensed voltage difference. Depending on a program state of a memory cell, a voltage level of the first node N1 may be different from a voltage level of the second node N2. The sense amplifier 156 may output a sensed result as differential signals SOUT and/SOUT, and the amplified voltage difference may be used to determine data read from the memory cell.

Meanwhile, the voltage latch-type sense amplifier illustrated in FIG. 22 may be somewhat different from the current latch-type sense amplifier described above. However, the effect of increasing the read margin described with reference to FIG. 13 may be obtained by adjusting the level of the second read current IRD2 of the sense amplifier 156 or the value of the reference resistor Rref. Accordingly, the embodiments of FIGS. 15 to 21 may be applied to the sensing circuit 150 of FIG. 22.

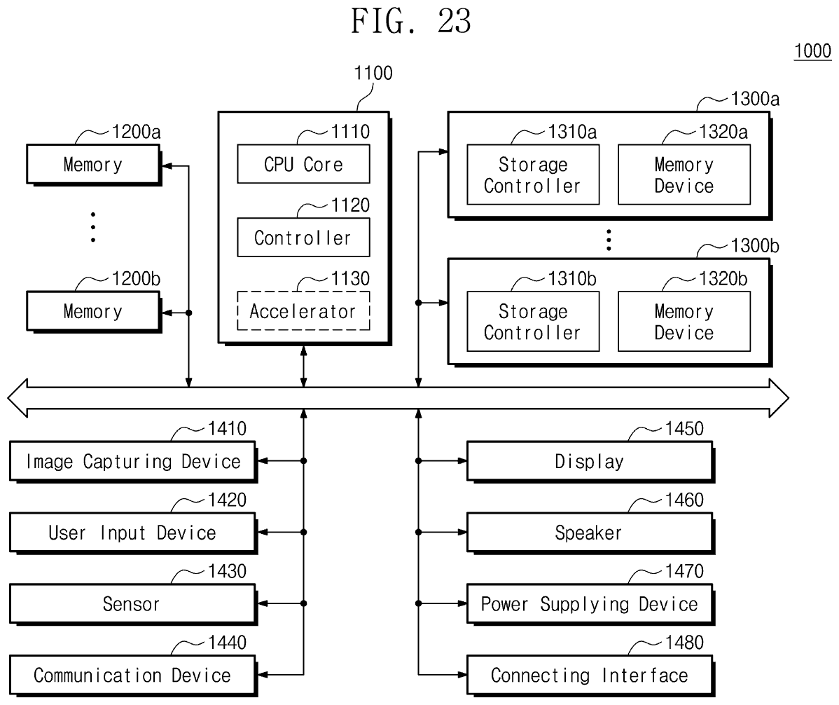

FIG. 23 is a diagram illustrating a system to which a memory device according to an embodiment of the present disclosure is applied.

The system 1000 may basically be a mobile system, such as a portable communication terminal (e.g., a mobile phone), a smartphone, a tablet personal computer (PC), a wearable device, a healthcare device, or an Internet of things (IoT) device. However, the system 1000 is not necessarily limited to the mobile system and may be a PC, a laptop computer, a server, a media player, or an automotive device (e.g., a navigation device).

The main processor 1100 may control all operations of the system 1000, more specifically, operations of other components included in the system 1000. The main processor 1100 may be implemented as a general-purpose processor, a dedicated processor, or an application processor.

The main processor 1100 may include at least one CPU core 1110 and further include a controller 1120 configured to control the memories 1200a and 1200b and/or the storage devices 1300a and 1300b. In some embodiments, the main processor 1100 may further include an accelerator 1130, which is a dedicated circuit for a high-speed data operation, such as an artificial intelligence (AI) data operation. The accelerator 1130 may include a graphics processing unit (GPU), a neural processing unit (NPU) and/or a data processing unit (DPU) and be implemented as a chip that is physically separate from the other components of the main processor 1100.

The memories 1200a and 1200b may be used as main memory devices of the system 1000. Although each of the memories 1200a and 1200b may include a volatile memory, such as static random access memory (SRAM) and/or dynamic RAM (DRAM), each of the memories 1200a and 1200b may include non-volatile memory, such as a flash memory, phase-change RAM (PRAM) and/or resistive RAM (RRAM). The memories 1200a and 1200b may be implemented in the same package as the main processor 1100. In an embodiment, each of the memories 1200a and 1200b may employ the memory device 100 in each of FIGS. 1, 14-16, 18, 21, and 22.

The storage devices 1300a and 1300b may serve as non-volatile storage devices configured to store data regardless of whether power is supplied thereto, and have larger storage capacity than the memories 1200a and 1200b. The storage devices 1300a and 1300b may respectively include storage controllers (STRG CTRL) 1310a and 1310b and NVMs (Non-Volatile Memories) 1320a and 1320b configured to store data via the control of the storage controllers 1310a and 1310b. Although each of the NVMs 1320a and 1320b may include a flash memory having a two-dimensional (2D) structure or a three-dimensional (3D) V-NAND structure, each of the NVMs 1320a and 1320b may include other type of NVM, such as PRAM and/or RRAM. In an embodiment, each of the NVMs 1320a and 1320b may employ the memory device 100 in each of FIGS. 1, 14-16, 18, 21, and 22.

The storage devices 1300a and 1300b may be physically separated from the main processor 1100 and included in the system 1000 or implemented in the same package as the main processor 1100. In addition, the storage devices 1300a and 1300b may have types of solid-state devices (SSDs) or memory cards and be removably combined with other components of the system 1000 through an interface, such as the connecting interface 1480 that will be described below. The storage devices 1300a and 1300b may be devices to which a standard protocol, such as a universal flash storage (UFS), an embedded multi-media card (eMMC), or a non-volatile memory express (NVMe), is applied, without being limited thereto. The image capturing device 1410 may capture still images or moving images. The image capturing device 1410 may include a camera, a camcorder, and/or a webcam.

The user input device 1420 may receive various types of data input by a user of the system 1000 and include a touch pad, a keypad, a keyboard, a mouse, and/or a microphone.

The user input device 1420 may receive various types of data input by a user of the system 1000 and include a touch pad, a keypad, a keyboard, a mouse, and/or a microphone.

The sensor 1430 may detect various types of physical quantities, which may be obtained from the outside of the system 1000, and convert the detected physical quantities into electric signals. The sensor 1430 may include a temperature sensor, a pressure sensor, an illuminance sensor, a position sensor, an acceleration sensor, a biosensor, and/or a gyroscope sensor.

The communication device 1440 may transmit and receive signals between other devices outside the system 1000 according to various communication protocols. The communication device 1440 may include an antenna, a transceiver, and/or a modem.

The display 1450 and the speaker 1460 may serve as output devices configured to respectively output visual information and auditory information to the user of the system 1000.

The power supplying device 1470 may appropriately convert power supplied from a battery (not shown) embedded in the system 1000 and/or an external power source, and supply the converted power to each of components of the system 1000.

The connecting interface 1480 may provide connection between the system 1000 and an external device, which is connected to the system 1000 and capable of transmitting and receiving data to and from the system 1000. The connecting interface 1480 may be implemented by using various interface schemes, such as advanced technology attachment (ATA), serial ATA (SATA), external SATA (e-SATA), small computer system interface (SCSI), serial attached SCSI (SAS), peripheral component interconnection (PCI), PCI express (PCIe), NVMe, IEEE 1394, a universal serial bus (USB) interface, a secure digital (SD) card interface, a multi-media card (MMC) interface, an eMMC interface, a UFS interface, an embedded UFS (eUFS) interface, and a compact flash (CF) card interface.

According to embodiments of the present disclosure, it may be possible to reduce the area and manufacturing costs by disposing normal cells of a magnetic memory device and OTP cells in one memory cell array.

According to embodiments of the present disclosure, it may be possible to improve durability of a memory device by minimizing an influence of OTP cells on normal cells adjacent thereto during an OTP write operation.

While the present disclosure has been described with reference to embodiments thereof, it will be apparent to those of ordinary skill in the art that various changes and modifications may be made thereto without departing from the spirit and scope of the present invention as set forth in the following claims.

What is claimed is:

1. A memory device comprising:
a memory cell array including a normal cell connected to a bit line and a one time program (OTP) cell connected to the bit line, wherein a program state of the normal cell is determined using a first reference resistance and a program state of the OTP cell is determined using a second reference resistance less than the first reference resistance;
a write driver configured to perform a first OTP write operation on the OTP cell; and
a sensing circuit configured to determine whether the first OTP write operation on the OTP cell is passed,
wherein the write driver is further configured to perform a second OTP write operation on the OTP cell when the first OTP write operation on the OTP cell is failed.

2. The memory device of claim 1, wherein the sensing circuit is configured to determine whether the first OTP write operation on the OTP cell is passed, by using a third reference resistance.

3. The memory device of claim 2, wherein a value of the second reference resistance is identical to a value of the third reference resistance.

4. The memory device of claim 2, wherein a value of the third reference resistance is smaller than a value of the second reference resistance.

5. The memory device of claim 2, wherein the sensing circuit includes:
a first clamping transistor configured to adjust a voltage level of a first node to which the OTP cell is connected; and
a second clamping transistor configured to adjust a voltage level of a second node to which a first reference resistor corresponding to the second reference resistance or a second reference resistor corresponding to the third reference resistance is connected.

6. The memory device of claim 5, wherein:
the first clamping transistor is configured to operate based on a first clamping voltage,
during a read operation on the OTP cell, the second clamping transistor is configured to operate based on a second clamping voltage,
during a verify operation on the OTP cell, the second clamping transistor is configured to operate based on a third clamping voltage, and
a level of the third clamping voltage is lower than a level of the second clamping voltage.

7. The memory device of claim 6, wherein:
the sensing circuit is configured to operate based on a sense amplifier enable signal,
the first clamping transistor is configured to operate based on the first clamping voltage,
the second clamping transistor is configured to operate based on the second clamping voltage, and
a first timing at which the sense amplifier enable signal is enabled during the verify operation on the OTP cell is earlier than a second timing at which the same amplifier enable signal is enabled during the read operation on the OTP cell.

8. The memory device of claim 1, wherein:
a level of a second write voltage applied to the OTP cell during the second OTP write operation is identical to a level of a first write voltage applied to the OTP cell during the first OTP write operation, and
a duration of the second write voltage is identical to a duration of the first write voltage.

9. The memory device of claim 1, wherein:
a level of a second write voltage applied to the OTP cell during the second OTP write operation is higher than a level of a first write voltage applied to the OTP cell during the first OTP write operation, and
a duration of the second write voltage applied to the OTP cell during the second OTP write operation is identical to a duration of the first write voltage applied to the OTP cell during the first OTP write operation.

10. The memory device of claim 1, wherein:
a level of a second write voltage applied to the OTP cell during the second OTP write operation is identical to a level of a first write voltage applied to the OTP cell during the first OTP write operation, and
a duration of the second write voltage applied to the OTP cell during the second OTP write operation is longer than a duration of the first write voltage applied to the OTP cell during the first OTP write operation.

11. The memory device of claim 1, wherein:
the sensing circuit is further configured to determine whether the second OTP write operation on the OTP cell is passed, and
the write driver is further configured to perform a third OTP write operation on the OTP cell when the second OTP write operation on the OTP cell is failed.

12. The memory device of claim 1, wherein each of the normal cell and the OTP cell includes:
a cell transistor including a first end, a second end connected to a source line, and a gate electrode connected to a word line; and
a magnetic tunnel junction element including a first end connected to the first end of the cell transistor and a second end connected to the bit line.

13. A memory device comprising:
a memory cell array including normal cells whose program states are determined using a first reference resistance and one time programmable (OTP) cells whose program states are determined using a second reference resistance less than the first reference resistance;
a write driver configured to perform a plurality of OTP write operations on the OTP cells; and
a sensing circuit configured to determine whether the plurality of OTP write operations are passed, by using a third reference resistance,
each of the normal cells and each of the OTP cells include a magnetic tunnel junction element.

14. The memory device of claim 13, wherein:
the sensing circuit includes:
a first clamping transistor configured to adjust a voltage level of a first node to which a first OTP cell among the OTP cells is connected; and
a second clamping transistor configured to adjust a voltage level of a second node to which a first reference resistor corresponding to the second reference resistance or a second reference resistor corresponding to the third reference resistance is connected,
the first clamping transistor is configured to operate based on a first clamping voltage,
during a read operation on the first OTP cell, the second clamping transistor is configured to operate based on a second clamping voltage,
during a verify operation on the first OTP cell, the second clamping transistor is configured to operate based on a third clamping voltage, and
a level of the third clamping voltage is lower than a level of the second clamping voltage.

15. The memory device of claim 13, wherein:
the sensing circuit includes:
a first clamping transistor configured to adjust a voltage level of a first node to which a first OTP cell among the OTP cells is connected; and
a second clamping transistor configured to adjust a voltage level of a second node to which a first reference resistor corresponding to the second reference resistance or a second reference resistor corresponding to the third reference resistance is connected,
the sensing circuit is configured to operate based on a sense amplifier enable signal,
the first clamping transistor is configured to operate based on a first clamping voltage,
the second clamping transistor is configured to operate based on a second clamping voltage, and
a first timing at which the sense amplifier enable signal is enabled during a verify operation on the first OTP cell is earlier than a second timing at which the sense amplifier enable signal is enabled during a read operation on the first OTP cell.

16. A method of operating a memory device in which a normal cell whose program state is determined using a first reference resistance and a one time programmable (OTP) cell whose program state is determined using a second reference resistance are connected to the same bit line, the method comprising:
performing a first OTP write operation on the OTP cell;
determining whether the first OTP write operation on the OTP cell is passed; and
performing a second OTP write operation on the OTP cell when the first OTP write operation on the OTP cell is failed,
wherein a value of the second reference resistance is less than a value of the first reference resistance.

17. The method of claim 16, wherein the determining of whether the first OTP write operation is passed is executed by using a third reference resistance different from the second reference resistance.

18. The method of claim 17, wherein a value of the third reference resistance is less than the value of the second reference resistance.

19. The method of claim 16, wherein:
a level of a second write voltage for the performing of the second OTP write operation is higher than a level of a first write voltage for the performing of the first OTP write operation, and/or
a duration of the second write voltage for the performing of the second OTP write operation is longer than a duration of the first write voltage for the performing of the first OTP write operation.

20. The method of claim 16, further comprising:
determining whether the second OTP write operation on the OTP cell is passed; and
performing a third OTP write operation on the OTP cell when the second OTP write operation on the OTP cell is failed.
